(19) United States
(12) Patent Application Publication
(10) Pub. No.: US 2023/0317458 A1
(43) Pub. Date: Oct. 5, 2023

(54) GAP FILL ENHANCEMENT WITH THERMAL ETCH

(71) Applicant: Applied Materials, Inc., Santa Clara, CA (US)

(72) Inventors: Kai WU, Palo Alto, CA (US); Xi CEN, San Jose, CA (US); Dixiong WANG, Milpitas, CA (US); Yang LI, Sunnyvale, CA (US); Peiqi WANG, Campbell, CA (US)

(21) Appl. No.: 17/887,292

(22) Filed: Aug. 12, 2022

Related U.S. Application Data
(60) Provisional application No. 63/327,719, filed on Apr. 5, 2022.

(51) Int. Cl. H01L 21/285; C23C 16/56; C23C 16/455; C23C 16/50; C23C 16/08

(52) U.S. Cl. CPC H01L 21/28568; C23C 16/56; C23C 16/45553; C23C 16/50; C23C 16/08

(57) ABSTRACT

A method of forming an interconnect structure over a substrate includes forming a nucleation layer over a surface of the substrate. The surface of the substrate comprises a plurality of openings, and the process of forming the nucleation layer includes (a) exposing the substrate to a tungsten-containing precursor gas to form a tungsten-containing layer over a surface of each of the plurality of openings, (b) exposing the formed tungsten-containing layer to an etchant gas, wherein exposing the tungsten-containing layer to the etchant gas etches at least a portion of the tungsten-containing layer disposed at a top region of each of the plurality of openings, and repeating (a) and (b) one or more times. The method further includes forming a bulk layer over the formed nucleation layer.

### CROSS-REFERENCE TO RELATED APPLICATIONS

This application claims priority to U.S. Provisional Application Ser. No. 63/327,719 filed Apr. 5, 2022, which is herein incorporated by reference in its entirety.

### BACKGROUND

### Field

Embodiments herein are directed to methods used in electronic device manufacturing, and more particularly, to methods used for forming conductive structures containing tungsten in a semiconductor device.

### Description of the Related Art

Tungsten (W) is widely used in integrated circuit (IC) device manufacturing to form conductive features where relatively low electrical resistance and relativity high resistance to electromigration are desired. For example, tungsten may be used as a metal fill material to form source contacts, drain contacts, metal gate fill, gate contacts, interconnects (e.g., horizontal features formed in a surface of a dielectric material layer), and vias (e.g., vertical features formed through a dielectric material layer to connect other interconnect features disposed there above and there below). Due to its relativity low resistivity and high melting point, tungsten is also commonly used to form bit lines and word lines used to address individual memory cells in a memory cell array of a dynamic random-access memory (DRAM) device.

As circuit densities increase and device features continue to shrink to meet the demands of the next generation of semiconductor devices, reliably producing tungsten features has become increasingly challenging. The advances in integrated circuit technology have necessitated improved methods depositing of refractory metals, particularly tungsten, to enhance the gap filling properties and reduce the stress of the same. Traditionally, the gap filling property and the stress are two characteristics of refractory metal layers that have been in conflict due to the competing desires to have a high deposition process throughput but also have a low level of stress and good gap fill characteristics.

Accordingly, there is a need for processes to form structures having a good gap fill characteristics.

### SUMMARY

Embodiments of the disclosure include flowing a molybdenum-based etchant (molybdenum halides, molybdenum oxy-halides) during tungsten CVD deposition (or any other metals that forms volatile products), the growth at field and top regions of the gap structures can be suppressed or etch away with minimum damage of the substrate.

Embodiments of the present disclosure provide a method of forming an interconnect structure over a substrate. The method includes forming a nucleation layer over a surface of the substrate. The surface of the substrate comprises a plurality of openings, and the process of forming the nucleation layer includes (a) exposing the substrate to a tungsten-containing precursor gas to form a tungsten-containing layer over a surface of each of the plurality of openings, (b) exposing the formed tungsten-containing layer to an etchant gas, wherein exposing the tungsten-containing layer to the etchant gas etches at least a portion of the tungsten-containing layer disposed at a top region of each of the plurality of openings, and repeating (a) and (b) one or more times. The method further includes forming a bulk layer over the formed nucleation layer.

Embodiments of the present disclosure provide a method of depositing a tungsten-containing layer. The method includes performing a nucleation process in a processing chamber. The nucleation process includes forming a tungsten-containing layer on a substrate by exposing a substrate to a first tungsten-containing precursor gas, and etching the formed tungsten-containing layer by delivering a molybdenum-based etchant gas to the substrate. The method further includes performing a deposition process in the processing chamber. The deposition process comprises forming a bulk layer by flowing a second tungsten-containing precursor gas.

Embodiments of the present disclosure provide a processing system. The processing system includes a processing chamber, and a system controller configured to cause the processing system to perform a nucleation process in the processing chamber. The nucleation process includes forming a tungsten-containing layer on a substrate by exposing a substrate to a first tungsten-containing precursor gas, and etching the formed tungsten-containing layer by delivering a molybdenum-based etchant gas to the substrate. The system controller further causes the processing system to perform a deposition process in the processing chamber. The deposition process comprises forming a bulk layer by flowing a second tungsten-containing precursor gas.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic cross-sectional view of a portion of a substrate having a tungsten-containing layer, according to one embodiment.

FIG. 1B is a schematic cross-sectional view of a portion of a substrate that includes a tungsten-containing layer that is pinching-off the top region of an opening formed in a substrate.

FIG. 1C is a schematic cross-sectional view of a portion of a substrate during different steps of a process used to form a tungsten-containing layer described in FIG. 3, according to one embodiment.

FIG. 2 is a schematic side view of a processing system that may be used to implement the methods set forth herein, according to one embodiment.

FIG. 3 illustrates a process flow used to form an interconnect structure on a substrate, according to some embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed to electronic device manufacturing and, more particularly, to systems and methods for forming a structure having a material layer that includes tungsten (W) in a semiconductor device manufacturing scheme.

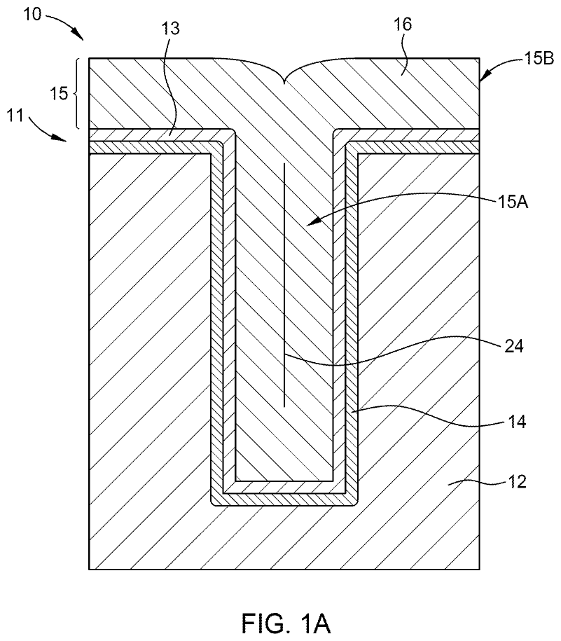

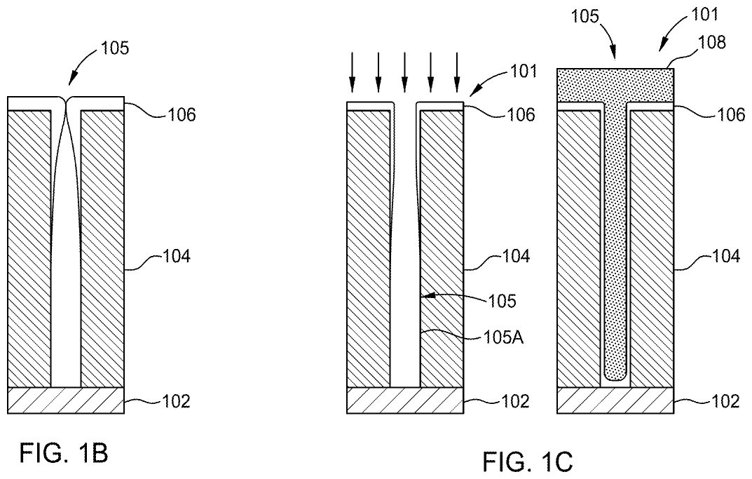

FIG. 1A is a schematic cross-sectional view of a substrate 10 illustrating a tungsten-containing interconnect structure. Here, the substrate 10 includes a patterned surface 11 including a dielectric layer 12 having a high aspect ratio opening formed therein (shown filled with a portion 15A of a tungsten-containing layer 15), a barrier material layer 14 deposited on the dielectric layer 12 to line the opening, and a portion 15B of the tungsten-containing layer 15 deposited on the barrier material layer 14.

The tungsten-containing layer 15 can be formed using a chemical vapor deposition (CVD), a plasma enhanced CVD, or atomic layer deposition (ALD) process where the tungsten-containing layer 15 is conformally deposited (grown) on the patterned surface 11 to fill the opening with the portion 15A, to cover a planar surface with the portion 15B, or a combination thereof. The structure includes a substantially uniform profile as the opening extends from the surface of the substrate 10 into the dielectric layer 12.

The barrier material layer 14 can include a material suitable for utilization as barrier layer, such as, but not limited to, titanium and tantalum, alloys, combinations, mixtures, and nitrides thereof. In one example, the barrier material layer 14 can be a titanium nitride (TiN) layer, deposited on the dielectric layer 12 to conformally line the openings and facilitate the subsequent deposition of a nucleation layer 13. In some embodiments, the barrier material layer 14 is deposited to a thickness of about 50 angstroms (Å) to about 150 Å.

In some embodiments, the tungsten-containing layer 15 includes the nucleation layer 13 and a bulk layer 16, which can be deposited using one or more of the methods described below. The nucleation layer 13 includes tungsten that is deposited using a CVD, ALD or even PVD process. The bulk layer 16 includes a tungsten-containing layer. In one example, the bulk layer 16 essentially comprises tungsten. In some embodiments, the thickness of the tungsten-containing layer 15 is about 20 Å to about 1800 Å.

Accordingly, embodiments herein provide a processing system that is configured to perform a combination of the individual aspects of the methods without transferring a substrate between processing chambers, thus improving overall substrate processing throughput and capacity for the tungsten gap fill processing schemes described herein. In some embodiments, certain method disclosed herein are selected based on the topology of the substrate surface. Specifically, certain methods may be used for substrates having high aspect ratio feature, such as about 10:1 or higher, and other method are suitable for substrates having a substantially planar surface, or having features having low aspect ratios.

Conventional CVD deposition processes have poor control on nucleation layer step coverage and thickness when filling high aspect ratio (AR>20) trenches and via with small critical dimensions (CD<10 nm). Conventional deposition processes used to form the nucleation layer can result in the formation of a large seam (e.g., seam 24 shown in FIG. 1A) in gap fill structures, especially when the top region of the openings is pinched off by the nucleation layer deposition. FIG. 1B illustrates a configuration where a nucleation layer 106 deposited on a dielectric layer 104 is “pinching-off” the top region of the high aspect ratio feature 105 formed on a substrate 102.

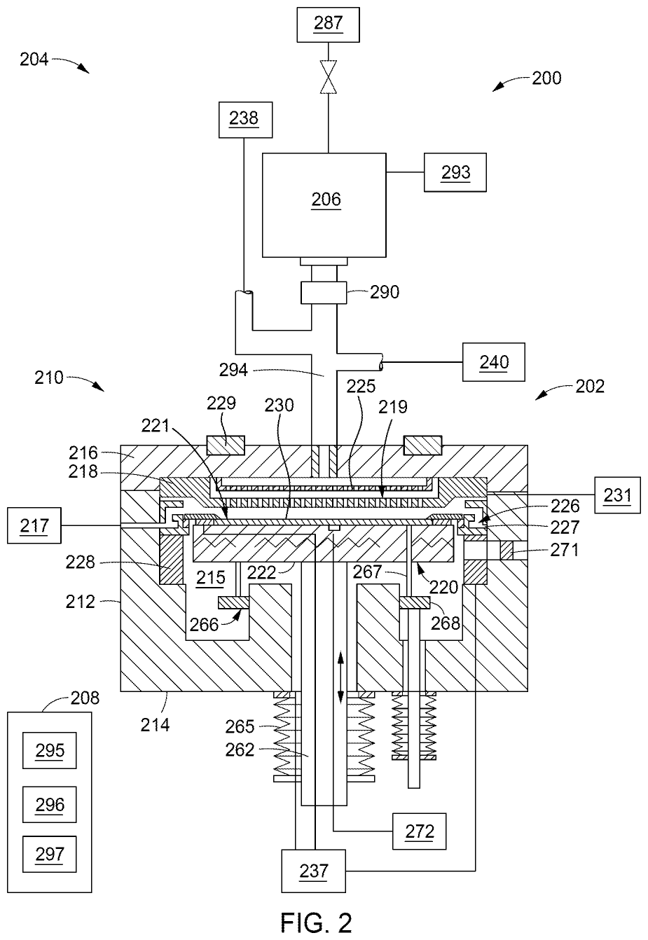

FIG. 2 schematically illustrate a processing system 200 that may be used to perform the processing methods described herein. Here, the processing system is configured to provide the processing conditions for each of a nucleation process, selective gap fill process, and surface deposition process within a single processing chamber 202, i.e., without transferring a substrate between a plurality of processing chambers. However, in some embodiments, the substrate is transferred from the processing chamber 202 to other processing chambers that can be used to deposit additional layers over the substrate.

As shown in FIG. 2, the processing system 200 includes a processing chamber 202, a gas delivery system 204 fluidly coupled to the processing chamber 202, and a system controller 208. The processing chamber 202 includes a chamber lid assembly 210, one or more sidewalls 212, and a chamber base 214, which collectively define a processing volume 215. The processing volume 215 is fluidly coupled to an exhaust 217, such as one or more vacuum pumps, used to maintain the processing volume 215 at sub-atmospheric conditions and to evacuate processing gases and processing by-products therefrom.

The chamber lid assembly 210 includes a lid plate 216 and a showerhead 218 coupled to the lid plate 216 to define a gas distribution volume 219 therewith. Here, the lid plate 216 is maintained at a desired temperature using one or more heaters 229 thermally coupled thereto. The showerhead 218 faces a substrate support assembly 220 disposed in the processing volume 215. As discussed below, the substrate support assembly 220 is configured to move a substrate support 222, and thus a substrate 230 disposed on the substrate support 222, between a raised substrate processing position (as shown) and a lowered substrate transfer position (not shown). When the substrate support assembly 220 is in the raised substrate processing position, the showerhead 218 and the substrate support 222 define a processing region 221.

The gas delivery system 204 is fluidly coupled to the processing chamber 202 through a gas inlet that is disposed through the lid plate 216. Processing or cleaning gases delivered, by use of the gas delivery system 204, flow through the gas inlet 223 into the gas distribution volume 219 and are distributed into the processing region 221 through the showerhead 218. In some embodiments, the chamber lid assembly 210 further includes a perforated blocker plate 225 disposed between the gas inlet 223 and the showerhead 218. In those embodiments, gases flowed into the gas distribution volume 219 are first diffused by the blocker plate 225 to, together with the showerhead 218, provide a more uniform or desired distribution of gas flow into the processing region 221.

The processing gases and processing by-products are evacuated radially outward from the processing region 221 through an annular channel 226 that surrounds the processing region 221. The annular channel 226 may be formed in a first annular liner 227 disposed radially inward of the one or more sidewalls 212 (as shown) or may be formed in the one or more sidewalls 212, which are used to protect the interior surfaces. In some embodiments, the processing chamber 202 includes one or more second liners 228 of the one or more sidewalls 212 or chamber base 214 from corrosive gases and/or undesired material deposition.

In some embodiments, a purge gas source 237 includes a first connection that is in fluid communication with the processing volume 215 so that it can be used to flow a chemically inert purge gas, such as argon (Ar), into a region disposed at a periphery of a substrate and/or beneath the substrate disposed on the substrate support 222, e.g., through the opening in the chamber base 214 surrounding the movable support shaft 262. The purge gas may be used to create a region of positive pressure below the substrate disposed on the substrate support 222 (when compared to the pressure in the processing region 221) during substrate processing. In some configurations, the purge gas is introduced through the chamber base 214 so that it flows upwardly therefrom and around the edges of the substrate support 222 to be evacuated from the processing volume 215 through the annular channel 226. In this configuration, the purge gas reduces undesirable material deposition on surfaces beneath the substrate support 222 by reducing and/or preventing the flow of material precursor gases thereinto.

The substrate support assembly 220 includes a movable support shaft 262 that sealingly extends through the chamber base 214, such as being surrounded by a bellows 265 in the region below the chamber base 214, and the substrate support 222, which is disposed on the movable support shaft 262. To facilitate substrate transfer to and from the substrate support 222, the substrate support assembly 220 includes a lift pin assembly 266 comprising a plurality of lift pins 267 coupled to or disposed in engagement with a lift pin hoop 268. The plurality of lift pins 267 are movably disposed in openings formed through the substrate support 222.

The substrate 230 is transferred to and from the substrate support 222 through a door 271, e.g., a slit valve disposed in one of the one or more sidewalls 212. Here, one or more openings in a region surrounding the door 271, e.g., openings in a door housing, are fluidly coupled to a purge gas source 237, e.g., an argon (Ar) gas source. The purge gas is used to prevent processing and cleaning gases from contacting and/or degrading a seal surrounding the door, thus extending the useful lifetime thereof.

The substrate support 222 is configured for vacuum chucking where the substrate 230 is secured to the substrate support 222 by applying a vacuum to an interface between the substrate 230 and the substrate receiving surface, such as with a vacuum source 272.

In some embodiments, the processing chamber 202 is configured for direct plasma processing. In those embodiments, the showerhead 218 may be electrically coupled to a first power supply 231, such as an RF power supply, which supplies power to form and maintain a capacitively coupled plasma using processing gases flowed into the processing region 221 through the showerhead 218. In some embodiments, the processing chamber 202 alternately comprises an inductively coupled plasma generator (not shown), and a plasma is formed through inductively coupling an RF power through an antenna disposed on the processing chamber 202 to the processing gas disposed in the processing volume 215.

The processing system 200 is advantageously configured to perform each of the tungsten nucleation, and bulk tungsten deposition processes without removing the substrate 230 from the processing chamber 202. The gases used to perform the individual processes, and to clean residues from the interior surfaces of the processing chamber, are delivered to the processing chamber 202 using the gas delivery system 204 fluidly coupled thereto.

Generally, the gas delivery system 204 includes one or more remote plasma sources, here radical generator 206, a deposition gas source 240, and the deposition gas source 240 to the chamber lid assembly 210. The gas delivery system 204 further includes an isolation valve 290, disposed between the radical generator 206 and the lid plate 216, which may be used to fluidly isolate the radical generator 206 from the processing chamber 202 and from other radical generators, if applicable (not shown). Deposition gases, e.g., tungsten-containing precursors, molybdenum-containing precursors, and reducing agents, are delivered from the deposition gas source 240 to the processing chamber 202 using a conduit system 294. The gas delivery system 204 further includes a purge gas source 237 to purge the conduit system 294.

The radical generator 206 is coupled to a power supply 293, such as a radio frequency (RF) power supply. The power supply 293 is used to ignite and maintain a plasma that is delivered to the plasma chamber volumes using gases provided from a corresponding gas source 287 fluidly coupled thereto.

Operation of the processing system 200 is facilitated by the system controller 208. The system controller 208 includes a programmable central processing unit, here the CPU 295, which is operable with a memory 296 (e.g., non-volatile memory) and support circuits 297. The CPU 295 is one of any form of general-purpose computer processor used in an industrial setting, such as a programmable logic controller (PLC), for controlling various chamber components and sub-processors. The memory 296, coupled to the CPU 295, facilitates the operation of the processing chamber. The support circuits 297 are conventionally coupled to the CPU 295 and comprise cache, clock circuits, input/output subsystems, power supplies, and the like, and combinations thereof coupled to the various components of the processing system 200 to facilitate control of substrate processing operations therewith.

The instructions in the memory 296 are in the form of a program product, such as a program that implements the methods of the present disclosure. In one example, the disclosure may be implemented as a program product stored on computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure.

### Deposition Process Example(s)

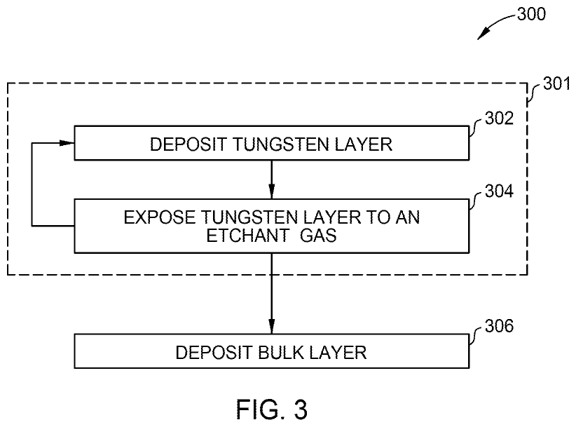

FIG. 3 depicts a process flow diagram of a method 300 used to deposit a tungsten-containing layer on a substrate according to some embodiments, which may be performed, at least in part, using the processing system 200. In some implementations, the processing system 200 is capable of operating in one or more process modes to form at least a portion of an interconnect structure, such as a pulsed CVD mode, a plasma enhanced CVD mode, and an ALD mode. FIG. 1C illustrates schematic cross-sectional side views of a structure 101 during the various processes performed during method 300. FIG. 1C depicts a substrate 102, which can include a silicon containing substrate (e.g., n-type Si substrate, p-type Si substrate) and one or more device layers formed thereon. A dielectric layer 104 is formed over the substrate 102. The dielectric layer 104 includes a feature 105 formed therein. In some embodiments, the feature 105 is a high-aspect ratio feature, such as a trench or via, that has an aspect ratio of >20 and a critical dimension of <10 nm.

The method 300 includes activity 301 in which a nucleation layer 106 is formed over a surface 105A of the feature 105. In some embodiments, the surface 105A can include a barrier layer and/or a liner layer formed over a surface of the dielectric layer 104. In one example, the surface 105A includes the barrier material layer 14 described above. In one embodiment, activity 301 includes a tungsten (W) layer deposition process 302 that is followed by a process (i.e., activity 304) where the deposited tungsten layer formed during activity 302 is exposed to an etchant gas.

During activity 302, in some embodiments, a tungsten layer is formed by use of an ALD process in which the substrate is exposed to a gas mixture including a tungsten-containing precursor gas (e.g., WF₆), and a hydrogen-containing gas (e.g., H₂). Alternately, the nucleation layer could be formed by use of a chemical vapor deposition (CVD), or a physical vapor deposition (PVD) process.

In activity 304, an etchant gas is provided to the substrate disposed in the processing region of the process chamber to etch a portion of the tungsten layer formed during activity 302. In one embodiment, the process performed during activity 304 includes a thermal based etching process that includes delivering a molybdenum-based etchant while the substrate is maintained at a temperature of between 20° C. and 550° C. It is believed that a thermally based etching process that utilizes a molybdenum-based etchant provides improved control over the etching and tungsten growth suppression process versus a plasma etching process. In this case, the exposure to an etchant gas containing molybdenum is used to etch and/or suppress the growth of subsequently deposited tungsten layers at the upper region of the feature 105 and thus reduce the amount of or eliminate the pinching-off of the upper portion of the feature 105 created by the formation of the nucleation layer 106 in the feature 105 during activity 302. In some embodiments, the etchant gas comprises a molybdenum halide and/or a molybdenum oxy-halide containing gas. In one example, the etchant gas comprises molybdenum hexafluoride (MoF₆). In another example, the etchant gas comprises molybdenum hexafluoride (MoF₆) and a carrier gas (e.g., Ar). In another example, the etchant gas comprises molybdenum hexafluoride (MoF₆), a carrier gas (e.g., Ar) and a hydrogen containing gas (e.g., H₂). In yet another example, a tungsten-containing gas (e.g., WF₆), a molybdenum based etchant gas (e.g., molybdenum hexafluoride (MoF₆)), a carrier gas (e.g., Ar) and a hydrogen containing gas (e.g., H₂) are co-flowed to achieve thinner nucleation layer with better step coverage.

In some embodiments, activity 304 is used as a method of tuning the tungsten layer's deposition profile formed on the substrate to improve gap fill in the subsequent activity 306. In one example, profile tuning can include preferential removal of portions of tungsten layer deposited on the field region and top area of the features formed in the substrate, and thus promote growth within the features from the bottom-up and reduce or prevent a seam from forming in the features.

During activity 301 the activities 302 and 304 are cyclically completed until a nucleation layer having a desired thickness is formed. In one example, the nucleation layer has a thickness of between about 10 Å and 30 Å.

In activity 306, a bulk layer 108 is deposited within the feature 105 using an ALD or CVD deposition process. In one embodiment, during activity 306, a tungsten-containing precursor gas is flowed at a rate of about 100 sccm to about 1500 sccm. In some embodiments, a hydrogen-containing gas, such as H₂, is co-flowed with the tungsten-containing precursor. The hydrogen-containing gas is flowed at a flow rate of about 3000 sccm to about 15000 sccm.

In one embodiment, during activity 306, a bulk layer 108 is deposited within the feature 105 using an ALD process. In activity 306, a pulsed amount of the tungsten-containing precursor gas is provided and then held within the processing region 221 for a duration of between about 1 second and about 10 seconds. Then a pulsed amount of a first purge gas is flowed between exposures of the tungsten precursors. The first purge gas includes an argon containing gas. In some embodiments, a pulsed amount of argon gas is then supplied at a purge time of about 1 second to about 5 seconds. The first purge gas may be delivered from the deposition gas source 240 or from the bypass gas source. A pulsed amount of a hydrogen-containing gas, such as H₂, can then be flowed after each exposure of the purge gas. The hydrogen-containing gas is flowed at a purge time of about 1 second to 5 seconds. A pulsed amount of a second purge gas can then be flowed after the hydrogen-containing gas, such as argon gas. The second purge gas condition can be substantially the same as the first purge gas condition. In some embodiment, the second purge gas time is about 1 second to about 5 seconds. The ALD process steps are then cyclically performed until the bulk layer is deposited to a predetermined thickness.

Alternately, in activity 306, a bulk layer 108 is deposited within the feature 105 using a plasma enhanced CVD deposition process. The tungsten-containing precursor gas is flowed at a rate of about 100 sccm to about 1500 sccm. The process may include exposing portions of the deposited tungsten-containing bulk layer 108 to a plasma formed by flowing one or more plasma processing gases, such as co-flowing a hydrogen-containing gas, such as H₂, and an argon-containing gas. The hydrogen-containing gas is flowed at a flow rate of about 500 sccm to about 3000 sccm. The argon-containing gas is flowed at a flow rate of about 500 sccm to about 3000 sccm. During this process an amount of RF power is applied by a power source to the argon-containing gas and the hydrogen-containing gas, such as a gas disposed in a processing region of a remote plasma source or to an antenna or electrode disposed on or within the processing system. In some embodiments, a power of about 50 W to about 600 W is applied at an RF frequency (e.g., 13.56 MHz) to the processing region of the remote plasma source or processing region of the processing system. In some embodiments, the plasma is injected in the processing volume between exposures of the deposition gases describes with respect to the chemical vapor deposition process. The plasma exposure time can be between about 0.5 seconds and about 5 seconds. The plasma pressure condition is about 3 Torr to about 30 Torr within the processing region of the processing system. The exposure to a tungsten-containing precursor and then exposure to a plasma may be cyclically performed until the bulk layer is deposited to a predetermined thickness. The substrate is heated to about 400° C. to about 550° C.

While the foregoing is directed to embodiments of the present disclosure, other and further embodiments of the disclosure may be devised without departing from the basic scope thereof, and the scope thereof is determined by the claims that follow.

What is claimed is:

1. A method of forming an interconnect structure over a substrate, comprising:
forming a nucleation layer over a surface of the substrate, wherein the surface of the substrate comprises a plurality of openings, and the process of forming the nucleation layer comprises:
(a) exposing the substrate to a tungsten-containing precursor gas to form a tungsten-containing layer over a surface of each of the plurality of openings;
(b) exposing the formed tungsten-containing layer to an etchant gas, wherein exposing the tungsten-containing layer to the etchant gas etches at least a portion of the tungsten-containing layer disposed at a top region of each of the plurality of openings; and
(c) repeating (a) and (b) one or more times; and
forming a bulk layer over the formed nucleation layer.

2. The method of claim 1, wherein the tungsten-containing precursor gas is selected from the group consisting of tungsten hexafluoride (WF₆), tungsten hexachloride (WCl₆), and a combination thereof.

3. The method of claim 1, wherein exposing the formed tungsten-containing layer to the etchant gas to etch the formed tungsten-containing layer is a thermal based etching process that is performed at a temperature between 20° C. and 550° C.

4. The method of claim 3, wherein the etchant gas comprises a molybdenum halide or a molybdenum oxy-halide.

5. The method of claim 4, wherein the etchant gas comprises molybdenum fluoride (MoF₆).

6. The method of claim 5, wherein the etchant gas comprises argon (Ar) and a hydrogen containing gas.

7. The method of claim 1, wherein the etchant gas comprises a molybdenum halide or a molybdenum oxy-halide.

8. The method of claim 7, wherein the etchant gas comprises molybdenum fluoride (MoF₆).

9. The method of claim 8, wherein the etchant gas comprises a hydrogen containing gas.

10. The method of claim 9, wherein the etchant gas comprises an inert gas.

11. A method of depositing a tungsten-containing layer, comprising:
performing a nucleation process in a processing chamber, the nucleation process comprising:
forming a tungsten-containing layer on a substrate by exposing a substrate to a first tungsten-containing precursor gas; and
etching the formed tungsten-containing layer by delivering a molybdenum-based etchant gas to the substrate; and
performing a deposition process in the processing chamber, the deposition process comprising forming a bulk layer by flowing a second tungsten-containing precursor gas.

12. The method of claim 11, further comprising:
repeating the nucleation process.

13. The method of claim 11, wherein the first and second tungsten-containing precursor gases are each selected from the group consisting of tungsten hexafluoride (WF₆), tungsten hexachloride (WCl₆), and a combination thereof.

14. The method of claim 11, wherein the etching of the formed tungsten-containing layer is performed at a temperature between 20° C. and 550° C.

15. The method of claim 11, wherein the molybdenum-based etchant gas is selected from the group consisting of molybdenum halide, molybdenum oxy-halide, and a combination thereof.

16. The method of claim 14, wherein the molybdenum-based etchant gas comprises molybdenum fluoride (MoF₆).

17. A processing system comprising:
a processing chamber; and
a system controller configured to cause the processing system to:
perform a nucleation process in the processing chamber, the nucleation process comprising:
forming a tungsten-containing layer on a substrate by exposing a substrate to a first tungsten-containing precursor gas; and
etching the formed tungsten-containing layer by delivering a molybdenum-based etchant gas to the substrate; and
perform a deposition process in the processing chamber, the deposition process comprising forming a bulk layer by flowing a second tungsten-containing precursor gas.

18. The processing system of claim 17, wherein the system controller is further configured to cause the processing system to repeat the nucleation process.

19. The processing system of claim 17, wherein
the first and second tungsten-containing precursor gases are each selected from the group consisting of tungsten hexafluoride (WF₆), tungsten hexachloride (WCl₆), and a combination thereof, and
the molybdenum-based etchant gas is selected from the group consisting of molybdenum halide, molybdenum oxy-halide, and a combination thereof.

20. The processing system of claim 17, wherein the etching of the formed tungsten-containing layer is performed at a temperature between 20° C. and 550° C.
